(19) United States
(12) Patent Application Publication
(10) Pub. No.: US 2006/0104101 A1
(43) Pub. Date: May 18, 2006

(54) MEMORY AND RELATED MANUFACTURING METHOD THEREOF

(76) Inventors: Wen-Lin Chen, Chia-Yi Hsien (TW); Yung-Chieh Yu, Hsin-Chu Hsien (TW); Po-Sen Wang, Hsin-Chu City (TW); Shih-Huang Huang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/904,573

(22) Filed: Nov. 17, 2004

(51) Int. Cl. G11C 5/06

(52) U.S. Cl. 365/63

(57) ABSTRACT

A memory manufactured through a semiconductor process includes a substrate, a memory cell array formed on the substrate, a peripheral circuit formed on the substrate and electrically connected to the memory cell array for controlling access of the memory cell array, and a power distribution network formed substantially above the peripheral circuit or the memory cell array. The power distribution network is electrically connected to the peripheral circuit and the memory cell array for providing power to the peripheral circuit and the memory cell array.

### BACKGROUND

The invention relates to memory and a related manufacturing method thereof, and more particularly, to an embedded memory with an improved power distribution network and related manufacturing method thereof.

It is well-known that memories have become essential elements of electronic products. For example, a cell phone, a computer system, and a personal digital assistant (PDA) all comprise memories to store data or program code for further data processing. Because of advances in the technology, the processing speed of the above-mentioned electronic products is getting faster, and the size of the electronic products is getting smaller. This also means that the size of memory has to be smaller and that the memory must be more efficient for accessing data.

Please refer to FIG. 1, which is a diagram of a memory 100 according to the related art. The memory 100 is manufactured through a semiconductor process and comprises a substrate 110, a memory cell array 120, a peripheral circuit 130, and a plurality of power rings 140a, 140b. Please note that the memory cell array 120, the peripheral circuit 130, and the power rings 140a, 140b are all formed on or above the substrate 110. Here, the memory cell array 120 comprises a plurality of memory cells (not shown) for storing data. The peripheral circuit 130 is utilized to access the memory cell array 120. For example, the peripheral circuit 130 includes an address decoder for locating one memory cell according to a received memory address information. As is known to those skilled in the art, some of the power rings 140a, 140b is connected to a power source (not shown) for delivering an operating voltage needed by the memory cell array 120 and the peripheral circuit 130. The others are grounded to provide the memory cell array 120 and the peripheral circuit 130 with a ground voltage. In addition, it is well-known that the power rings 140a, 140b are formed above the substrate 110 and surround the memory cell array 120 and the peripheral circuit 130. Therefore, the power rings 140a, 140b are electrically connected to the memory cell array 120 and the peripheral circuit 130 through a plurality of conducting wires (not shown).

This power ring configuration causes two major problems. The first problem is an I-R drop phenomenon. That is, because the memory cell array 120 and the peripheral circuit 130 are both connected to the power rings 140a, 140b, currents flow through the conducting wires between the inner circuits (i.e., the memory cell array 120 and the peripheral circuit 130) and the outer power rings 140a, 140b.

This phenomenon causes addition power consumption and undesired voltage drops on the conducting wires. Therefore, the performance of the inner circuit is degraded and the power consumption is increased. Furthermore, the second problem is the space wasted by the power rings. That is, assume that the size of the memory cell array 120 becomes larger because the number of memory cells inside the memory cell array is increased. If the processing speed of the memory is raised, the operating frequency of the memory is higher, and charging/discharging currents of the memory cell array 120 and 130 have to be greater, accordingly. Therefore, the width of the power rings 140a, 140b has to be broader to adequately transfer the needed charging/discharging currents. Because the power rings 140a, 140b are built outside the inner circuits, the power rings 140a, 140b occupy a lot of space of the memory 100, which greatly increases the memory chip area.

### SUMMARY

It is therefore one objective of the claimed invention to provide a memory, especially for an embedded memory, with an improved power distribution network and a related manufacturing method thereof, to solve the above-mentioned problems.

According to an exemplary embodiment of the claimed invention, a memory manufactured through a semiconductor process is disclosed, and the memory comprises: a substrate; a memory cell array formed on the substrate; a peripheral circuit formed on the substrate and electrically connected to the memory cell array for controlling access of the memory cell array; and a power distribution network formed substantially above the peripheral circuit or the memory cell array, the power distribution network electrically connected to the peripheral circuit and the memory cell array for providing power to the peripheral circuit and the memory cell array.

Furthermore, a method of manufacturing a memory through a semiconductor process is disclosed. The method comprises: providing a substrate; forming a memory cell array on the substrate; forming a peripheral circuit on the substrate, and electrically connecting the peripheral circuit to the memory cell array for controlling access of the memory cell array; and forming a power distribution network substantially above the peripheral circuit or the memory cell array, and electrically connecting the power distribution network to the peripheral circuit and the memory cell array for providing power to the peripheral circuit and the memory cell array.

The present invention memory and the memory manufacturing method have an improved power distribution network so that the present invention reduces the space of a memory chip and avoids an unwanted I-R drop phenomenon to make the memory chip work more efficiently and have a smaller chip area.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a diagram of a memory according to the related art.

FIG. 2 is a diagram of a memory according to a first embodiment of the present invention.

FIG. 3 is a diagram of a memory according to a second embodiment of the present invention.

FIG. 4 is a diagram of a memory having two memory cell arrays according to a third embodiment of the present invention.

FIG. 5 is a diagram of a memory having two memory cell arrays and guard rings according to a fourth embodiment of the present invention.

### DETAILED DESCRIPTION

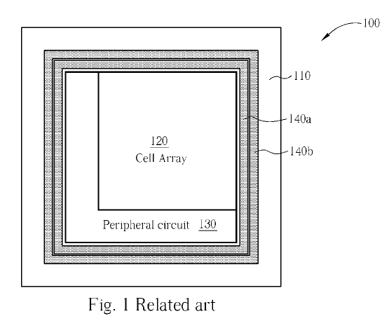

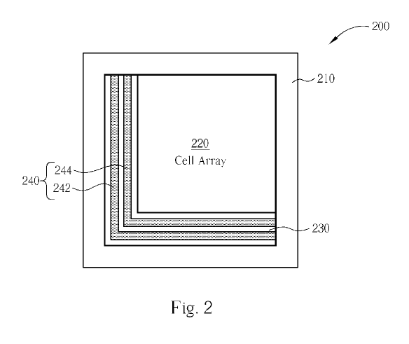

Please refer to FIG. 2, which is a diagram of a memory 200 according to a first embodiment of the present invention. In this embodiment, the memory 200 comprises a substrate 210, a memory cell array 220, a peripheral circuit 230, and a power distribution network 240. Please note the components of the same name in the FIG. 1 and FIG. 2 have the same functionality and operation. Therefore, a repeated description is omitted here for brevity.

As shown in FIG. 2, the memory cell array 220 and the peripheral circuit 230 are formed on the substrate; however, the power distribution network 240 is formed above the peripheral circuit 230 instead of being directly formed on the substrate 210. According to the semiconductor process, several metal connecting layers can be formed above the substrate 210. Generally speaking, a standard 0.25 μm semiconductor process allows 5-6 metal connecting layers to be built above the substrate 210. Here, the memory cell array 220 often occupies 4-5 layers, but the peripheral circuit 230 only occupies 2-3 layers. Therefore, the upper layers of the peripheral circuit 230, such as the 4^{th}, 5^{th}, and 6^{th} layers, can be utilized to accommodate the power distribution network 240. That is, the power distribution network 240 can be formed within a region of an upper metal layer (maybe the 4^{th} layer), where the region is above the peripheral circuit 230. As mentioned above, the power distribution network 240 is electrically connected to the peripheral circuit 230 for supplying the required operating voltage and ground voltage. In this embodiment, the power distribution network 240 comprises a plurality of conducting lines 242, 244. For example, the conducting line 242 acts as a power line to deliver the operating voltage, and the conducting line 244 serves as a ground line to provide the ground voltage. Since the power distribution network 240 is formed above the peripheral circuit 230, the power distribution network 240 can be electrically connected to the peripheral circuit 230 through shorter conducting wires. As a result, the above-mentioned I-R drop phenomenon is suppressed because the length of the conducting path is greatly shortened. Furthermore, the chip size of the memory 200 is also reduced because the space preciously occupied by the related art power rings 140a, 140b is eliminated according to the present invention.

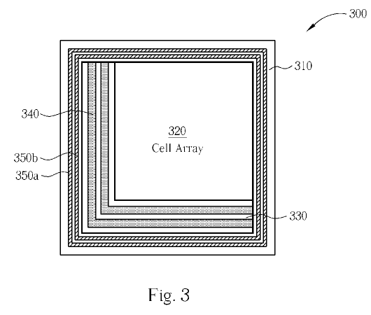

Please refer to FIG. 3, which is a diagram of a memory 300 according to a second embodiment of the present invention. The memory 300 comprises a substrate 310, a memory cell array 320, a peripheral circuit 330, and a power distribution network 340. The memory 300 is quite similar to the memory 200 shown in FIG. 2. The structure, operations, and functions of the substrate 310, the memory cell array 320, and the peripheral circuit 330 are all the same as the substrate 110, the memory cell array 120 and peripheral circuit 130 of the first embodiment accordingly. The only difference between the first embodiment and the second embodiment is the guard rings 350a, 350b, which are positioned outside the inner circuits (i.e., the memory cell array 320, the peripheral circuit 330, and the power distribution network 340). The guard rings 350a, 350b are utilized for preventing the memory cell array 320, the peripheral circuit 330, and the power distribution network 340 from being affected by undesired noise. Each of the guard rings 350a, 350b has a minimum line width capable of being manufactured by the semiconductor process, which occupies only negligible space. For example, the guard ring 350a grounded is electrically connected to a N+ region to form a N+/PW junction, and the guard ring 350b with predetermined voltage is electrically connected to a P+ region to form a P+/NW junction. As a result, the function of the N+/PW junction and the P+/NW junction are to reduce incoming external noise.

Please note that in the first and second embodiments, the power distribution network is formed on the peripheral circuit. But in fact, the power distribution network can also be formed above the memory cell array or on any available regions of upper layers. These alternative designs all fall into the metes and bounds of the present invention.

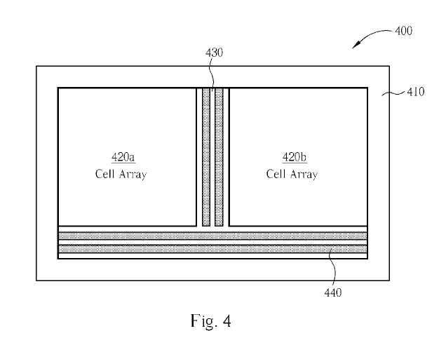

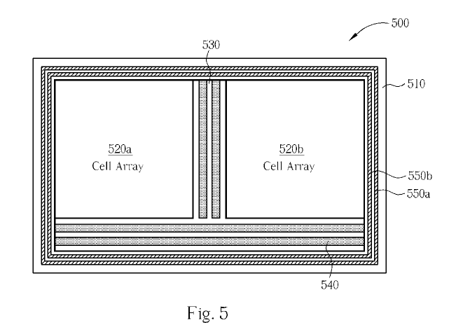

Furthermore, please note that in the first and second embodiments, the number of the memory cell arrays is only meant to serve as an example and is not meant to be taken as a limitation. In other words, the present invention power distribution network can be applied to a memory having a plurality of memory cell arrays. Please refer to FIG. 4, which is a diagram of a memory 400 having two memory cell arrays 420a, 420b according to a third embodiment of the present invention. Furthermore, please refer to FIG. 5, which is a diagram of a memory 500 having two memory cell arrays 520a, 520b and guard rings 550a, 550b according to a fourth embodiment of the present invention. Please note that the components of the same name in these embodiments have the same functionality and operation. Therefore, a repeated description is skipped for brevity.

In addition, each of the power distribution networks 240, 340, 440, 540 respectively shown in FIGS. 2-5 has two conducting lines for delivering the operating voltage and the ground voltage. However, the number of the conducting lines is not limited, and the above-mentioned configurations are only used to serve as examples.

Please note that each of the above-mentioned memories 200, 300, 400, 500 can be integrated with a logic core to store data processed by the logic core. In other words, each of the memories 200, 300, 400, 500 is an embedded memory for the logic core formed inside the same chip.

In contrast to the related art, the memory and the manufacturing method according to the present invention provide an improved power distribution network so that the present invention memory can save the space when allocating the related art power rings and alleviate the related art I-R drop phenomenon to make the memory chip work more efficiently and have a smaller chip area.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory manufactured through a semiconductor process, the memory comprising:
a substrate;
a memory cell array formed on the substrate;
a peripheral circuit formed on the substrate and electrically connected to the memory cell array for controlling access of the memory cell array; and
a power distribution network substantially formed above the peripheral circuit or the memory cell array, the power distribution network electrically connected to the peripheral circuit and the memory cell array for providing power to the peripheral circuit and the memory cell array.

2. The memory of claim 1 further comprising:
at least a guard ring formed on the substrate and surrounding the memory cell array and the peripheral circuit for protecting the memory cell and the peripheral circuit from noise.

3. The memory of claim 2 wherein the guard ring has a line width being a minimum line width capable of being manufactured by the semiconductor process.

4. The memory of claim 1 being an embedded memory.

5. A method of manufacturing a memory through a semiconductor process, the method comprising:
providing a substrate;
forming a memory cell array on the substrate;
forming a peripheral circuit on the substrate, and electrically connecting the peripheral circuit to the memory cell array for controlling access of the memory cell array; and
forming a power distribution network substantially above the peripheral circuit or the memory cell array, and electrically connecting the power distribution network to the peripheral circuit and the memory cell array for providing power to the peripheral circuit and the memory cell array.

6. The method of claim 5 further comprising:
forming at least a guard ring on the substrate, and surrounding the memory cell array and the peripheral circuit with the guard ring for protecting the memory cell and the peripheral circuit from noise.

7. The method of claim 6 wherein the guard ring has a line width being a minimum line width capable of being manufactured by the semiconductor process.

8. The method of claim 5 wherein the memory is an embedded memory.
